(19) United States
(12) Patent Application Publication
(10) Pub. No.: US 2024/0318317 A1
(43) Pub. Date: Sep. 26, 2024

(54) SUBSTRATE COATED WITH AT LEAST ONE DIAMOND-LIKE CARBON LAYER PROTECTED BY A GERMANIUM OR GERMANIUM OXIDE TEMPORARY LAYER

(71) Applicant: SAINT-GOBAIN GLASS FRANCE, COURBEVOIE (FR)

(72) Inventors: Jean-Thomas FONNE, AULNAY-SOUS-BOIS (FR); Denis GUIMARD, PARIS (FR); Lorenzo MANCINI, ORSAY (FR); Nadia ZENID, EPINAY SUR SEINE (FR)

(21) Appl. No.: 18/575,699

(22) PCT Filed: Jun. 29, 2022
(86) PCT No.: PCT/FR2022/051298

§ 371 Date: Dec. 29, 2023

(30) Foreign Application Priority Data
Jun. 30, 2021 (FR) FR2107026

(51) Int. Cl. C23C 28/04; C23C 14/06; C23C 14/08; C23C 14/18; C23C 14/35; C23C 14/58; C23C 16/26; C23C 16/50; C23C 16/56; C23C 28/00

(52) U.S. Cl. CPC C23C 28/046; C23C 14/0652; C23C 14/086; C23C 14/185; C23C 14/35; C23C 14/5806; C23C 16/26; C23C 16/50; C23C 16/56; C23C 28/322; C23C 28/343

(57) ABSTRACT

A substrate coated with a stack of layers includes the following series of layers, starting from the surface of the substrate: a layer of diamond-like carbon DLC; a germanium or germanium oxide layer having a thickness of between 2 and 40 nm, the germanium or germanium oxide layer including less than 20% tin; and optionally, an oxygen barrier layer.

The present invention relates to a substrate provided with a coating or a stack of layers comprising at least one layer of diamond-like carbon (DLC), on which at least one temporary protective layer (also called sacrificial layer) is deposited, which is a layer of germanium or germanium oxide having a thickness of between 2 and 40 nm, said layer of germanium or germanium oxide comprising less than 20% tin. The invention also relates to the method for manufacturing a heat-treated substrate which is coated with a stack of layers comprising at least one layer of diamond-like carbon.

The thin layers of diamond-like carbon (denoted “DLC layer”) are known to improve the scratch resistance of the underlying substrate by substantially reducing its surface friction coefficient, as well as to increase its hardness. These amorphous so-called “DLC” carbon layers comprise carbon atoms in a mixture of sp2 and sp3 hybridization states.

There is also abundant literature on methods for producing DLC coatings. For example, document WO 2004/071981 A1 describes a method for depositing DLC layers by ion beam. Document CN 104962914 A describes a vapor phase deposition device for the industrial production of DLC layers. Document CN 105441871 A relates to a device for physical vapor deposition and high-performance pulsed magnetron sputtering for the production of thick DLC coatings. Document WO 2016/171627 A1 relates to the coating of a substrate comprising a DLC type carbon layer, which is formed by means of physical vapor deposition, for example by means of high-power pulsed magnetron sputtering. Document JP 2011068940 A relates to a method for producing abrasion resistant DLC layers.

In numerous applications, it is necessary for substrates comprising DLC layer-type coatings to be heat treated. In the case of glass substrates, these may for example be thermal tempering treatments intended to mechanically strengthen the substrate by creating strong compressive stresses at its surface. However, DLC coatings are not stable at high temperatures, in particular under an oxygen atmosphere. Indeed, at high temperatures, the amorphous DLC carbon layers undergo drastic structural changes, even to the point of “burning.” Thus, DLC coatings deposited on glass substrates undergoing heat treatments requiring temperatures ranging up to 800° C., under an oxygen atmosphere, such as tempering, annealing or bending, simply disappear if they are not protected from oxidation.

Two main methods are known to provide DLC layers resistant to heat treatments. The first method is based on the silicon doping of the DLC layers themselves in order to improve the resistance to high temperatures during a heat treatment. In the other method, additional protective layers (so-called sacrificial layers) that can be removed are used to protect the DLC layer against oxygen in order to prevent combustion of the DLC layer during the heat treatment. These protective layers are also removable after the heat treatment.

Thus, document U.S. Pat. No. 7,060,322 B2 describes a glass substrate provided with a coating wherein the DLC layer is provided with a protective layer of zirconium nitride. The protective layer prevents the DLC layer from being significantly burned and can be removed after heat treatment. Document U.S. Pat. No. 8,580,336 B2 describes a coating of a glass substrate comprising a DLC layer, wherein a first and a second inorganic layer are arranged on the DLC layer. The first layer comprises zinc oxide and nitrogen. Document US 20080182033 A1 describes a similar coating comprising a first optional zinc oxide layer and a second tin oxide layer. Document U.S. Pat. No. 8,443,627 B2 relates to a glass substrate coated with at least one layer comprising diamond-like carbon (DLC) and a protective film covering the latter. The protective film comprises two layers of oxygen-substoichiometric zinc oxide in order to prevent oxidation of the DLC layer on the glass. This document also describes a protective film comprising a first layer of magnesium oxide or oxygen-substoichiometric zinc (called “release layer”) deposited on a layer of DLC, and a second layer called oxygen barrier layer of aluminum nitride or silicon carbide, deposited on said first layer. However, in this document the first layer must be relatively thick (>100 nm) in order to obtain satisfactory protection of the DLC layer. In addition, the removal of the protective film after heat treatment of the coated substrate is quite tedious and may, for example, require washing with acetic acid solutions. Document WO 2019/020485 describes a system of several sacrificial layers in order to protect the DLC layer from oxidation during a heat treatment. This document in particular discloses a substrate provided with a coating comprising, starting from said substrate, the layers in the following order: a DLC layer, a metal single-layer or multi-layer comprising tin or magnesium, and an oxygen barrier layer.

The disadvantage of these sacrificial layers (metal layers and oxygen barrier layer) is that they are difficult to remove after heat treatment of the coated substrate. This is due in part to the adhesion between the metal layer(s) mentioned above and the DLC layer. Indeed, although the sacrificial layers are degraded during the heat treatment, the complete elimination of these layers, without altering the DLC layer, requires not only washing with water with or without other solvents but especially mechanical friction, carried out for example using washing machines and/or brushes. However, these apparatuses are not part of standard cleaning equipment or cleaning protocols that can be used in industrial scale processes.

The Applicant has therefore sought a temporary protective layer or a temporary protective system for a substrate coated with at least one layer of diamond-like carbon (DLC) that can be easily removed without solvents or mechanical friction, after heat treatment of said coated substrate, while retaining the mechanical properties (including anti-scratch properties) of the DLC layer. Thus, the temporary protection must allow the coated substrate to undergo a heat treatment without altering or without negatively affecting the DLC layer and its properties. Furthermore, the temporary protection must be sufficiently stable to allow protection of the surface of the substrate coated with the DLC layer before heat treatment during the manufacturing, transformation, handling, transportation and/or storage operations.

To this end, an object of the invention is a substrate coated with a stack of layers comprising the following series of layers starting from the surface of said substrate:
a layer of diamond-like carbon DLC,
a germanium or germanium oxide layer having a thickness of between 2 and 40 nm, preferably between 2 and 20 nm, said germanium or germanium oxide layer comprising less than 10% tin, and
optionally, an oxygen barrier layer.

It was surprisingly observed by the inventors that a germanium or germanium oxide layer, optionally topped with an oxygen barrier layer according to the invention, could ensure the protection of a DLC layer deposited on a substrate whether before, during or after heat treatment of said substrate, and that such a layer (or a stack of layers comprising said layer and the oxygen barrier layer) could be easily removed by simple washing with water without using solvents and/or mechanical friction after the heat treatment of said substrate. Indeed, it has been observed by the inventors that after heat treatment and simple washing with water of the substrate initially coated with the aforementioned layer or stack of layers, the DLC layer was still present on the substrate and its mechanical properties, in particular anti-scratch properties, were perfectly preserved, as demonstrated by the following examples.

Furthermore, the coating of the substrate according to the invention had good mechanical stability and good aging stability before the heat treatment.

The term “coated” is intended to mean that the layer coating the substrate or another layer is deposited on top of the substrate or this other layer, but not necessarily in contact with them. When a first layer is arranged “on top of” a second layer (or “surmounts” a second layer), it is understood that the first layer is further from the substrate than the second layer.

The substrate according to the invention is preferably made of ceramic, glass-ceramic or glass, and more preferentially made of glass. The glass is in particular of the soda-lime-silica type but it can also be a glass of borosilicate or aluminosilicate type. The soda-lime-silica glass may be clear or tinted. In a preferred embodiment, the substrate is a glass panel. The thickness of the substrate, in particular of a glass substrate, may vary between 0.1 mm and 20 mm, in particular between 2 and 8 mm.

The substrate coated with a stack of layers according to the invention thus comprises the series of the following layers, starting from the surface of said substrate:
a layer of diamond-like carbon DLC,
a germanium or germanium oxide layer having a thickness of between 2 and 40 nm, preferably between 2 and 20 nm, said germanium or germanium oxide layer comprising less than 20% tin, and
optionally, an oxygen barrier layer.

Of these three layers, the layer of diamond-like carbon DLC is therefore situated closest to the substrate. The germanium or germanium oxide layer is disposed above the DLC layer; and the optional oxygen barrier layer is disposed above said germanium or germanium oxide layer.

Advantageously, each of said films is in direct contact with the preceding one.

Even more advantageously, the stack of layers consists essentially of the DLC layer and the germanium or germanium oxide layer, in this order, starting from the surface of said substrate. In this case, an oxygen barrier layer is not necessary, offering the advantage of reducing the number of layers of the stack and consequently of reducing the number of sacrificial layers to be eliminated after the heat treatment of the coated substrate since only the germanium or germanium oxide layer is to be eliminated. Indeed, in this preferred embodiment, the germanium or germanium oxide layer itself behaves as an oxygen barrier layer.

Preferably, the stack of layers according to the invention does not comprise a layer of Ag, Au, Cu and Ni. Indeed, in known stacks of layers having silver-based functional layers (that is to say they act on solar radiation), these silver-based layers are temporarily protected by a DLC layer which this time is sacrificial and is removed. However, the DLC layer according to the invention is a functional layer that is absolutely to be preserved.

Furthermore, diamond-like carbon layers, also called “DLC”, according to the invention are well known to the art according to this simple designation without it being necessary to explain their composition in greater detail. These layers of diamond-like carbon are amorphous carbon layers that may or may not contain hydrogen. And the carbon atoms in a DLC layer can be in a mixture of sp2 and sp3 hybridization states, the proportion of sp3 hybridized carbons being able to be greater than the proportion of sp2 hybridized carbons or vice versa. Indeed, four large families of amorphous carbon can be distinguished, depending on whether the carbon contains hydrogen or not, and according to the proportion of sp3 hybridization:
amorphous carbons, denoted a-C (predominant sp2 hybridization) or ta-C (preponderance sp3 predominant),
hydrogenated amorphous carbons denoted a-C:H (predominant sp2 hybridization) or ta-C:H (preponderance sp3 predominant).

The DLC layers according to the present invention in particular include all these families.

Furthermore, the DLC layer used according to the invention may be doped or not doped, in other words the DLC layer may comprise atoms other than carbon and hydrogen, such as for example silicon, oxygen, nitrogen, a metal or fluorine, as a dopant, or else without them.

The person skilled in the art knows various methods for manufacturing DLC layers. DLC layers are generally deposited on the substrate by a vapor phase deposition process, for example by physical vapor deposition (PVD) or by chemical vapor deposition (CVD), and preferably by sputtering. The preferred methods of deposition used are: plasma-enhanced chemical vapor deposition (PECVD) and ion beam deposition. In the PECVD process, hydrocarbons, in particular alkanes and alkynes, such as C₂H₂ or CH₄, can be used as precursors for the DLC layer to be deposited.

According to a preferred embodiment, the DLC layer is formed by plasma-enhanced chemical vapor deposition (PECVD). In this method, the plasma is generated by a magnetron or a magnetron target. The coating of the substrate (said substrate can further comprise at least one ion diffusion barrier layer between the substrate and the DLC layer to be formed) is carried out in a vacuum chamber, in which a magnetron provided with the target and the substrate are arranged. At least one reactive gas is introduced into the chamber under vacuum, for example at a pressure of 0.1 μbar (microbar) to 10 μbar, the plasma generated by the target of the magnetron causes the formation of fragments of the reactive gas, which are deposited on the substrate to form the DLC layer. The reactive gas may, for example, comprise hydrocarbons, in particular alkanes and alkynes, such as C₂H₂ or CH₄, or organosilicon compounds, such as tetramethylsilane. Optionally, additional inert gases, such as argon, can be introduced into the vacuum chamber to improve the plasma. The target of the magnetron may, for example, consist of silicon, which is optionally doped with one or more elements, such as aluminum and/or boron, or made of titanium. The manufacturing of the DLC layer using the PECVD method by magnetron is advantageous because it makes it possible to coat large substrate surfaces with good stability of the method, without high heating of the substrate being necessary. The DLC layers thus produced have a very good scratch resistance and good optical properties, in particular when said method is used in the target poisoning mode, known to the person skilled in the art.

The diamond-like carbon DLC layer may have a thickness of between 1 and 20 nm, preferably between 2 and 10 nm, and more preferentially between 3 and 8 nm. These layer thicknesses are advantageous because a high transparency of the layers is thus ensured.

The germanium or germanium oxide layer, according to the invention, has a thickness of between 2 and 40 nm, preferably between 2 and 20 nm and comprises less than 20% tin, preferably less than 10%.

Preferably, the germanium or germanium oxide layer is tin-free.

In an alternative embodiment, said layer may comprise between 1 and 20 atomic % of a metal or a metalloid other than germanium, in particular chosen from antimony, copper, lead, silver, zinc, indium, gallium, aluminum, bismuth, manganese, cadmium, iron, strontium, zirconium, thorium, lithium, nickel, chromium, silicon, tin, gadolinium, yttrium, calcium, or a mixture thereof.

The germanium or germanium oxide layer may comprise at least 50 atomic % germanium or at least 50 atomic % germanium oxide, preferably at least 80 atomic % germanium or at least 80 atomic % germanium oxide, and even more preferentially at least 90 atomic % germanium or at least 90 atomic % germanium oxide. Advantageously, the germanium oxide or germanium oxide layer consists essentially of germanium or germanium oxide.

The germanium or germanium oxide layer may further comprise nitrogen, in particular nitrogen only present in the form of unavoidable impurities.

In a preferred embodiment, the germanium or germanium oxide layer consists essentially of germanium (denoted “Ge”).

And, in another preferred embodiment, the germanium or germanium oxide layer consists essentially of germanium oxide. The term “germanium oxide” in the present invention refers in particular to an oxide of formula “GeOₓ” with x between 0.01 and 2, limits included, preferably the value of x is between 1 and 2. In particular, the value of x is equal to 2, which corresponds to the stoichiometric compound “GeO₂”.

The germanium or germanium oxide layer can be deposited and therefore formed by magnetron-assisted cathode sputtering.

The inventors surprisingly observed that the germanium or germanium oxide layer according to the invention, which is deposited above the DLC layer (which is itself deposited above the substrate) was soluble in water after heat treatment of said coated substrate; thus allowing simple and rapid removal by simple washing with water said germanium or germanium oxide layer and optional layers placed above (such as oxygen barrier layers).

In the particular case where the germanium or germanium oxide layer consists essentially of germanium, the inventors noticed surprisingly that this layer was not water-soluble before the heat treatment of the coated substrate thus making the stack stable during storage, but that this layer oxidizes during the heat treatment then becoming water-soluble after said heat treatment, thus enabling its removal by washing with water (after heat treatment of said coated substrate).

Furthermore, according to the invention, “temporary protective layer” or “sacrificial layer” is understood to mean a layer which is removed after heat treatment, in particular by washing with water. Thus, according to the invention, such layers are germanium or germanium oxide layers and the optional oxygen barrier layers arranged above said germanium or germanium oxide layers.

The coating of the substrate may further comprise an oxygen barrier layer arranged above the abovementioned germanium or germanium oxide layer. The role of the oxygen barrier layer is to protect (in addition to the germanium or germanium oxide layer) the DLC layer, in particular against the ambient oxygen. Thus, the oxygen barrier layer, in addition to the germanium or germanium oxide layer, makes it possible to subject the coated substrate to a heat treatment (such as tempering), without causing partial or complete degradation of the DLC layer.

Such oxygen barrier layers and their formation are well known from the prior art. Conventional materials can be used for this purpose. The vapor phase deposition methods, such as PVD or CVD, and preferably by magnetron sputtering, or thin atomic layer deposition (ALD), can be used for the application of the oxygen barrier layer above the germanium or germanium oxide layer mentioned above.

Thus, the oxygen barrier layer may comprise or may consist essentially of at least one material selected from the group consisting of silicon carbide, silicon oxide, silicon nitride, silicon oxynitride, metal oxide, metal nitride, metal carbide, or a mixture thereof. In the case of metal oxides, nitrides and carbides, the metal can be chosen from the following metals: titanium, zirconium, hafnium, vanadium, niobium, tantalum, chromium, molybdenum or tungsten.

In a preferred embodiment, the oxygen barrier layer comprises or consists essentially of silicon nitride, in particular of Si₃N₄ and/or doped Si₃N₄; the Si₃N₄ doped with Al, Zr, Ti, Hf and/or B being particularly preferred and the Si₃N₄ doped with Zr being most preferred. With the exception of B, the proportion of the doping elements (in particular Al, Zr, Ti and/or Hf) in doped Si₃N₄ may be in the range from 1% to 40 atomic %. The proportion of B as doping element may be between 0.1 ppm and 100 ppm.

The combination of the germanium or germanium oxide layer described above with an oxygen barrier layer allows better protection of the DLC layer, in particular when the oxygen barrier layer is a doped Si₃N₄ layer, preferably doped with Zr. The oxygen barrier layer arranged above the germanium or germanium oxide layer, according to the invention, also makes it possible to reduce the thickness of the germanium or germanium oxide layer and consequently to reduce the cost of the stack; germanium being an expensive element, in particular in its oxide form or in its metallic form entering the composition of a magnetron target. Furthermore, an even more advantageous embodiment is the combination of the germanium or germanium oxide layer and an oxygen barrier layer comprising silicon nitride, in particular as described above.

The oxygen barrier layer may have a thickness of between 2 and 100 nm, preferably between 20 and 80 nm, and more preferentially between 30 and 80 nm.

In principle, the DLC layer is deposited directly and in contact with the substrate surface but according to a possible alternative, the substrate coating may further comprise at least one ion diffusion barrier layer between the substrate and the DLC diamond type carbon layer, said ion diffusion barrier layer preferably consisting essentially of silicon carbide, silicon oxide, silicon nitride, silicon oxynitride, metal oxide, metal nitride, metal carbide, or a mixture thereof, and more preferentially Si₃N₄ and/or doped Si₃N₄, and even more preferentially of Si₃N₄ doped with Al, Zr, Ti, Hf and/or B. In the case of metal oxides, nitrides and carbides, the metal can be chosen from the following metals: titanium, zirconium, hafnium, vanadium, niobium, tantalum, chromium, molybdenum or tungsten.

The ion diffusion barrier layer makes it possible to prevent the undesirable diffusion of ions, such as sodium ions, from the substrate to the coating and in particular during the heat treatment.

Such ion diffusion barrier layers and their formation are well known from the prior art. Conventional materials can be used for this purpose. Vapor phase deposition methods, such as PVD or CVD, by sputtering, preferably by magnetron sputtering, or thin atomic layer deposition (ALD), can be used for the application of the ion diffusion barrier layer.

The ion diffusion barrier layer may have a thickness of between 1 and 100 nm, preferably between 5 and 50 nm.

Preferably, each of the layers of the stack described above is in direct contact with the preceding one.

In an advantageous embodiment, the substrate, and in particular the glass substrate, provided with at least one DLC layer and one or more optional layers of ion diffusion barrier or oxygen barrier, is transparent. In other words, the light transmission in the visible range, for example as measured according to European standard NF EN 410 (2011), is greater than 50%, preferably greater than 70%, and in particular greater than 80%.

While the application more particularly targeted by the invention is glazing for interior furnishings, other applications can be envisaged, in particular in vehicle glazings. Thus, the heat-treated substrate coated with a stack of layers, according to the invention, can be used as a glass table or as a shower wall or else as a vehicle window.

The invention also relates to the method for manufacturing a heat-treated substrate coated with a stack of layers comprising at least one layer of diamond-like carbon DLC. This method comprises the following steps:
the heat treatment of a substrate coated with a stack of layers as described above, preferably at a temperature of between 300° C. and 800° C. for a duration of between 1 min and 20 min, at a pressure of 1 atm (atmosphere),
the elimination of the germanium or germanium oxide layer and of the optional oxygen barrier layer by washing said heat-treated coated substrate with water.

The heat treatment step may be a tempering, an annealing or a bending, preferably a tempering. The heat treatment can be carried out at a temperature of between 300° C. and 800° C., preferably between 500° C. and 700° C., and more preferentially between 600° C. and 700° C. The duration of the heat treatment can vary between 1 and 20 min, preferably between 2 and 5 min.

In a preferred embodiment, the heat treatment is a tempering, preferentially carried out at a temperature of 700° C., for a period of 3 minutes and at a pressure of 1 atm.

The step of heat-treating the coated substrate according to the invention is followed by a step of washing said heat-treated coated substrate with water, which makes it possible to eliminate, in other words completely remove, the temporary protective layer comprising the germanium or germanium oxide layer and the optional oxygen barrier layer, without affecting the DLC layer deposited on the substrate (in particular without affecting the mechanical properties referred to as “anti-scratch” of said DLC layer). The water washing step can be carried out at a pH of between 6 and 8.5, preferably at a pH approximately equal to 7, at ambient temperature in a range of from 15° C. to 40° C.

For the purposes of the present invention, “washing with water” is understood to mean that the sacrificial layer (that is, the germanium or germanium oxide layer and the optional oxygen barrier layer described above) are removed completely or eliminated, that is:
by depositing water on the surface of the layer(s) side of the heat-treated coated substrate for a period of from 1 min to 20 min, preferably from 1 min to 5 min, or
by immersion in water of the heat-treated coated substrate for a period of from 1 min to 20 min, preferably from 1 min to 5 min, or
by spraying agitated water or pressurized water onto the surface of the layer(s) side of the heat-treated coated substrate; for example water would be projected by nozzles onto said substrate, or
by simple wiping with a water-soaked cloth, fabric or paper.

In the present description, “elimination of the germanium or germanium oxide layer and the optional oxygen barrier layer,” or “eliminated germanium or germanium oxide and the optional oxygen barrier layer(s)” when viewed on the DLC layer of the stack of the coated heat-treated substrate is understood to mean residue-free following said washing with water, that is, the DLC layer is clean.

The method according to the invention makes it possible to obtain heat-treated substrates provided with a DLC layer having good mechanical properties.

Because the germanium oxide or germanium oxide layer and the oxygen barrier layer, according to the invention, are completely removed from the heat treated substrate provided with at least one DLC layer by simple washing with water without using solvents or mechanical friction, the method according to the invention is suitable for manufacturing a heat treated substrate with a DLC layer on an industrial scale, since no particular washing equipment is necessary.

The invention and its advantages are described in more detail below by means of the following non-limiting comparative examples according to the invention.

### EXAMPLES

In example 1a according to the invention, a glass substrate has been covered with a stack of layers comprising the following series of layers, starting from the surface of said glass substrate:
an ion diffusion barrier layer Si₃N₄ having a thickness of 15 nm,
a layer of diamond-like carbon DLC having a thickness of 5 nm, and
a germanium layer (denoted Ge) having a thickness of 10 nm.

In example 1b according to the invention, a glass substrate has been covered with a stack of layers comprising the following series of layers starting from the surface of said glass substrate:
an ion diffusion barrier layer Si₃N₄ having a thickness of 15 nm,
a layer of diamond-like carbon DLC having a thickness of 5 nm, and
a layer of germanium oxide having a thickness of 10 nm.

In example 2 according to the prior art, a glass substrate has been covered with a stack of layers comprising the following series of layers starting from the surface of said glass substrate:
an ion diffusion barrier layer Si₃N₄ having a thickness of 15 nm,
a layer of diamond-like carbon DLC having a thickness of 5 nm, and
a metal layer of tin (denoted Sn) having a thickness of 10 nm.

In comparative example 3, the glass substrate is coated starting from said substrate only with said ion diffusion barrier layer Si₃N₄, then the DLC layer; no temporary protective layer is deposited above the DLC layer.

In all these examples, the substrate is a glass substrate of Planiclear® type (sold by Saint-Gobain Glass France) and has a thickness of 4 mm.

In all these examples, the DLC layer is deposited by magnetron-assisted chemical vapor deposition, that is, by the PECVD method with C₂H₂ as precursor. The other layers are deposited by magnetic field assisted sputtering (often referred to as magnetron sputtering).

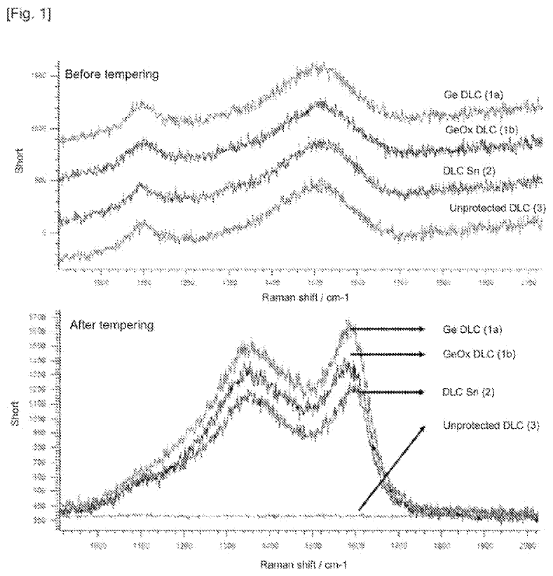

### Raman Spectroscopy, FIG. 1

Raman spectroscopy is carried out on each of the coated substrates described above before a heat treatment consisting of tempering and after tempering, in order to observe the molecular composition of the DLC layer. In other words, it involves determining whether the DLC layer is indeed present on each of the substrates, by measuring the presence of the carbon-carbon bonds “denoted C—C”, which compose said DLC layer. Thus, the measurements are carried out using a Raman spectrometer equipped with a laser source having a wavelength of 532 nm and a power of 50 mW, with a magnification objective of ×100, of a network of 2400 lines/mm and of an input slot set to 20 μm. The sample exposure time is typically 20 s.

The tempering for these tests consists in heating the substrates 1a, 1b, 2 and 3 to a temperature of 700° C. for 3 min, at a pressure of 1 atm, followed by rapid cooling.

The results reported on the Raman spectra in FIG. 1 show that:
before tempering, all the spectra of all the coated substrates have two very convolutional peaks, the first of which is situated at approximately 1390 cm⁻¹ and the second at 1545 cm⁻¹. These peaks are typical of carbon-carbon bonds of a diamond-like carbon DLC layer, then
after tempering, no peak corresponding to the C—C bonds is observed for the substrate without protective coating of example 3 due to the complete disappearance of the DLC layer.

Substrates whose DLC layer was protected either by a layer of germanium or germanium oxide (examples 1a and 1b, according to the invention) have two peaks at approximately 1370 cm⁻¹ and 1590 cm⁻¹ whose relative positions and intensities are comparable to that of a DLC layer protected by tin such as in example 2 (according to the prior art).

Thus, the germanium or germanium oxide layer according to the invention ensures the protection of a DLC layer deposited on a substrate during a heat treatment.

### Scratch Resistance Test

In order to evaluate the mechanical strength and more particularly the scratch resistance of the glass substrates of examples 1a and 1b, after tempering and after removal of the layer of germanium or germanium oxide by washing with water, these substrates are subjected to the test described below.

Balls made of borosilicate with a diameter of 10 mm are subjected to an increasing force (uniform increase of the force from 0 N to 30 N by increasing the fall height, speed of 30 N/min) onto the glass substrates coated with at least one layer of DLC (obtained from examples 1a and 1b, according to the invention, after heat treatment and after removal of the layer of germanium or germanium oxide by washing with water) and, by way of comparison, onto the uncoated glass substrate coated with DLC layer (glass obtained from example 3, after tempering and therefore after disappearance of the DLC layer).

From about 5 N force, the borosilicate spheres left deep scratches on the uncoated glass substrate but no scratch is observed on the heat treated coated glass substrates.

This test shows that a germanium or germanium oxide layer according to the invention makes it possible not only to protect a substrate coated with at least one DLC layer during a heat treatment but also to preserve the anti-scratch properties of said DLC layer after its removal.

Optical Results of Coated Substrates Heat Treated after Washing Step

In another experiment, the optical properties were measured of a glass substrate according to example 2: glass/Si₃N₄/DLC/Sn (according to the prior art) and of a glass substrate according to example 1a: glass/Si₃N₄/DLC/Ge (according to the invention); these substrates having been subjected to certain conditions, as described below.

Indeed, the measurements were carried out either:
after tempering each of the substrates (denoted “Tr”), or
after tempering each of the substrates, followed by rubbing using a wet cloth (denoted “Tr+Fr”) in order to remove the tin or germanium layer, or
after tempering each of the substrates, followed by depositing a water drop for 2 minutes on the layer to be removed (denoted “Tr+Gt”).

In these examples, the tempering was carried out at a temperature of 700° C., for 3 min, at a pressure of 1 atm.

The measurements of the optical properties of said glass substrates are consequently carried out according to European standard NF EN 410 (2011). More precisely, the light transmissions T_{L} and the light reflections side(s) R_{Lc}, are measured in the visible spectrum range: wavelengths between 380 nm and 780 nm, according to illuminant D₆₅. The colorimetry parameters a* and b* are measured according to the international colorimetry model (L, a*, b*).

The results obtained are compiled in Tables 1 below:

TABLE 1

| | T_{L} (%) | R_{Lc} (%) | a* | b* |
|---|---|---|---|---|
| in Transmission | | | | |
| Ex. 2 (Tr) | 38.02 | | 3.46 | −2.05 |
| Ex. 2 (Tr + Fr) | 83.83 | | −0.67 | 2.12 |
| Ex. 2 (Tr + Gt) | 38.39 | | 3.44 | −1.88 |
| Ex. 1a (Tr) | 80.3 | | −0.37 | 3.4 |
| Ex. 1a (Tr + Fr) | 82.56 | | −0.56 | 3.59 |
| Ex. 1a (Tr + Gt) | 82.25 | | −0.54 | 3.66 |
| In Reflection | | | | |
| Ex. 2 (Tr) | | 27.89 | −1.22 | 16.96 |
| Ex. 2 (Tr + Fr) | | 11.51 | −0.36 | −3.94 |
| Ex. 2 (Tr + Gt) | | 27.98 | −1.27 | 16.6 |
| Ex. 1a (Tr) | | 18.42 | −0.84 | −6.43 |
| Ex. 1a (Tr + Fr) | | 16.31 | −0.44 | −7.75 |
| Ex. 1a (Tr + Gt) | | 16.42 | −0.45 | −7.78 |

The results reported in the table show that the germanium layer is removed using a single drop of water whereas the metal layer of tin requires additional friction to be completely removed.

Indeed, as reported in the preceding tables, the values T_{L}, R_{Lc} and a*, b* obtained for the glass substrate according to example 1a (Tr+Fr) are identical to the values T_{L}, R_{Lc} and a*, b* obtained with the glass substrate Ex. 1a (Tr+Gt), which shows that the germanium layer can be removed by simple washing with water.

On the contrary, the values T_{L}, R_{Lc} and a*, b* obtained for the glass substrate according to example 2 (according to the prior art) after tempering (Tr) are identical to the values T_{L}, R_{Lc} and a*, b* obtained with the glass substrate Ex. 2 (Tr+Gt). This shows that a simple washing with water does not allow the elimination of the protective layer Sn but that an additional friction step is necessary.

Such results show the advantage of using a germanium layer in an industrial application, since the user can remove it by simple washing without the need to use more restrictive means such as brushes or equivalents.

Furthermore, results similar to those obtained with a glass substrate according to example 1a: glass/Si₃N₄/DLC/Ge (according to the invention) were obtained with a glass substrate whose germanium layer was replaced by a layer of germanium oxide; glass/Si₃N₄/DLC/GeOₓ.

1. A substrate coated with a stack of layers comprising the following series of layers starting from the surface of said substrate:
a layer of diamond-like carbon DLC,
a germanium or germanium oxide layer having a thickness of between 2 and 40 nm, said germanium or germanium oxide layer comprising less than 20% tin, and
optionally, an oxygen barrier layer.

2. The coated substrate according to claim 1, wherein said germanium or germanium oxide layer is tin-free.

3. The coated substrate according to claim 1, wherein the stack of layers does not comprise a layer based on Ag, Au, Cu and Ni.

4. The coated substrate according to claim 1, wherein the diamond-like carbon DLC layer has a thickness of between 1 and 20 nm.

5. The coated substrate according to claim 1, wherein when the oxygen barrier layer is present, the oxygen barrier layer comprises at least one material selected from the group consisting of silicon carbide, silicon oxide, silicon nitride, silicon oxynitride, metal oxide, metal nitride, metal carbide, or a mixture thereof.

6. The substrate according to claim 1, wherein the optional oxygen barrier layer has a thickness of between 2 and 100 nm.

7. The coated substrate according to claim 1, wherein the stack of layers further comprises at least one ion diffusion barrier layer between the substrate and the diamond-like carbon DLC layer.

8. The coated substrate according to claim 7, wherein the ion diffusion barrier layer has a thickness of between 1 and 100 nm.

9. The coated substrate according to claim 1, wherein the substrate is made of ceramic, glass-ceramic, or glass.

10. The coated substrate according to claim 1, wherein the layer of germanium or germanium oxide consists essentially of germanium or germanium oxide.

11. The substrate according to claim 1, wherein each of said layers of the stack is in direct contact with a preceding one.

12. The coated substrate according to claim 1, wherein the stack of layers consists essentially of said layer of diamond-like carbon DLC and of said germanium or germanium oxide layer, in this order, starting from the surface of said substrate.

13. A method for manufacturing a heat-treated substrate coated with a stack of layers comprising at least one layer of diamond-like carbon DLC, the method comprising:
heat treating a substrate coated with a stack of layers according to claim 1, at a temperature comprised between 300° C. and 800° C. for a duration of between 1 min and 20 min at a pressure of 1 atm,
removing the germanium or germanium oxide layer and the optional oxygen barrier layer by washing said heat-treated coated substrate with water.

14. The method for manufacturing a substrate according to claim 13, wherein the heat treating is chosen from tempering, annealing and bending treatments.

15. The coated substrate according to claim 1, wherein the thickness of the germanium or germanium oxide layer is between 2 and 20 nm.

16. The coated substrate according to claim 4, wherein the thickness of the diamond-like carbon DLC layer is between 3 and 8 nm.

17. The coated substrate according to claim 5, wherein the oxygen barrier layer comprises Si₃N₄ and/or Si₃N₄ doped with Al, Zr, Ti, Hf and/or B.

18. The substrate according to claim 6, wherein the optional oxygen barrier layer has a thickness of between 30 and 80 nm.

19. The coated substrate according to claim 7, wherein ion diffusion barrier layer consists essentially of silicon carbide, silicon oxide, silicon nitride, silicon oxynitride, metal oxide, metal nitride, metal carbide, or a mixture thereof.

20. The coated substrate according to claim 8, wherein the ion diffusion barrier layer has a thickness of between 5 and 50 nm.
